(19) United States
(12) Patent Application Publication
(10) Pub. No.: US 2017/0135220 A1
(43) Pub. Date: May 11, 2017

(54) Printable Films for Printed Circuit Boards and Processes for Making Same

(71) Applicant: THE GOVERNING COUNCIL OF THE UNIVERSITY OF TORONTO, Toronto (CA)

(72) Inventors: Perumal Varun Chadalavada, Toronto (CA); Daniel Wigdor, Toronto (CA)

(73) Assignee: THE GOVERNING COUNCIL OF THE UNIVERSITY OF TORONTO, Toronto (CA)

(21) Appl. No.: 15/330,844

(22) Filed: Nov. 7, 2016

Related U.S. Application Data
(60) Provisional application No. 62/252,422, filed on Nov. 7, 2015.

(51) Int. Cl. H05K 3/02; H05K 1/09

(52) U.S. Cl. CPC H05K 3/027; H05K 1/092; H05K 2201/032; H05K 2201/0335; H05K 2203/068

(57) ABSTRACT

Film for use in preparing a printed circuit board (PCB) along with methods for making a PCB and producing a printable film are described herein. The film includes a first layer formed of a radiation-transparent material, a second layer formed of a curable adhesive material, a third layer formed of an electrically conductive material, and optionally, a fourth layer formed of an adhesive and a fifth layer formed of a removable material. Through the adhesive layers, the layers are bonded together to produce the printable film. To produce a PCB, the first layer is covered in ink distributed in a pattern representing the PCB, and the ink-covered film is exposed to radiation until the non-ink-covered portions of the second layer have cured. Then, the fifth layer is removed tearing away the electrically conductive material associated with the non-ink-covered portions of the second layer producing the PCB.

### FIELD OF THE INVENTION

The present specification relates generally to the fabrication of Printed Circuit Boards (PCBs), and more specifically to printable films and methods that allow end users to make PCBs that are possible using standard office inkjet or laser printers, using standard inks.

### BACKGROUND OF THE INVENTION

Printed Circuit Boards (PCBs) form the structural and connective underpinnings of electronic assemblies. Nearly every electronic device contains one or more PCBs on which the functional components such as integrated circuits (ICs), resistors and other passive components, connectors, etc. are placed. PCBs function to provide power to the various components, enable communication, and act as a mechanical support structure to allow the assembly to be fixed into enclosures.

Despite their prominence, building physical electronics prototypes is presently cumbersome. Industrial processes, such chemical etching, require significant equipment and potentially hazardous materials, and may take days or weeks to complete. Rapid prototyping methods such as silver inks are expensive and require special equipment. For rapid, inexpensive prototyping, developers must resort to bread boarding or other ad hoc wiring methods that limit their ability to produce high fidelity prototypes. Without the ability to effectively fabricate PCBs quickly, users cannot rapidly build and iterate on the design and development of physical objects that possess computational abilities, or the degree of “smartness” necessary, to sense the environment, interact with users, or communicate with the digital world.

The growing popularity and availability of easy-to-use digital fabrication systems, such as laser cutters and 3D printers, has granted a broad range of users' unprecedented access to manufacturing tools that allow for the rapid fabrication of functional mechanical prototypes and custom designed objects. The rise of the Maker movement and easy-to-use embedded electronics platforms such as the Arduino™ and Raspberry Pi™ has made the process of creating electronics prototypes more accessible and seamless. Physically building and testing these prototypes with fidelity and a variety of electronic parts on PCBs remains one of the few encumbrances to the rapid production of electronic-enhanced custom-objects.

Accordingly, there remains a need for improvements in the art.

### SUMMARY OF THE INVENTION

In accordance with an aspect of the invention, there is provided a film for use in the preparation of a printed circuit board (PCB), comprising: a first layer formed of a radiation-transparent material; a second layer formed of a curable adhesive material, the second layer adjacent to and adhered to the first layer, the adhesive material being curable via exposure to radiation; and a third layer formed of an electrically conductive material, the third layer adjacent to and adhered to the second layer.

In accordance with a further aspect of the invention, there is provided a method of creating a printed circuit board (PCB), comprising: taking a printable film, the printable film comprising: a first layer formed of a radiation-transparent material; a second layer formed of a curable adhesive material, the adhesive material being curable via exposure to radiation; a third layer formed of an electrically conductive material; depositing ink on to the radiation-transparent layer of the film, the ink distributed in a pattern representing the PCB; exposing the ink-covered film to radiation, the radiation curing the curable adhesive material; and removing part of the third layer of conductive material such that portions of the electrically conductive material remain in the pattern to form the PCB.

In accordance with a further aspect of the invention, there is provided a method of producing a printable film for use in the preparation of a printed circuit board, comprising: bonding a plurality of layers into the printable film, the layers including: a first layer formed of a radiation-transparent material; a second layer formed of a curable adhesive material, the adhesive material being curable via exposure to radiation, bonded to the first layer; and a third layer formed of an electrically conductive material, bonded to the second layer.

Other aspects and features according to the present application will become apparent to those ordinarily skilled in the art upon review of the following description of embodiments of the invention in conjunction with the accompanying figures.

### BRIEF DESCRIPTION OF THE DRAWINGS

Reference will now be made to the accompanying drawings which show, by way of example only, embodiments of the invention, and how they may be carried into effect, and in which:

FIG. 1 is an exploded view of a PCB film according to an embodiment of the invention; and

FIG. 2 is a flow diagram of successive steps a, b, c and d in a PCB creation process according to an embodiment;

FIGS. 3A and 3B show a PCB for an Arduino™ Shield made according to an embodiment;

FIGS. 4A and 4B show a PCB for a moisture sensor made according to an embodiment;

FIGS. 5A and 5B show a PCB for a shortcut pad made according to an embodiment; and

FIGS. 6A and 6B show a PCB for a paper speaker made according to an embodiment.

Like reference numerals indicated like or corresponding elements in the drawings.

### DETAILED DESCRIPTION OF THE EMBODIMENTS

The present invention and the embodiments described herein are directed to a PCB film for use in creating PCBs, which can be carried out even using a standard laser or inkjet printer using standard inks.

Several approaches have been taken to develop faster electronics prototyping tools. However, these approaches face either the pitfalls of oversimplification by reducing the system to the point that not all electronic components can be supported, or require expensive, specialized machinery that reduces the adoption and proliferation of their approach. Prior work of relevance to the present project generally falls under one of two categories: industrial PCB fabrication or rapid electronics prototyping.

Industrial PCB Fabrication

The PCB was invented in the 1930s, and was popularized following its use in munitions by the United States during World War H. Since that time, the production and development of printed circuit boards has evolved significantly following the rapid demand and development of electronic goods. Various methods have been developed to cater to different needs in production times, scale, and quality. These industrial systems have been setup with cost, repeatability, and robustness of yield in mind.

A complete review of PCB materials and manufacturing is beyond the scope and requirements of the present application, however, the most common method of industrial fabrication of PCBs is chemical etching of a copper-clad laminate. PCB substrates such as fiberglass, Bakelite, and Kapton are pre-coated with a layer of copper; a mask is then used to transfer the circuit pattern onto the board. This mask protects the desired copper, allowing the rest of the copper to be etched away using chemicals. Different techniques can be employed in the generation of this mask. In one approach, a silkscreen printing method coats the copper-clad laminates with ink that is resistant to the etching solutions that dissolve the copper. For PCBs requiring a higher resolution, a uniform coating of a photosensitive chemical can be exposed to a projected optical image of the PCB layout. The exposed parts of the photosensitive chemical become resistant to the etching chemical and form a mask, which is then cleaned away using industrial solvents. While reliable and high-yield, the need for safe handling of these chemicals makes this process unsuitable for in-office production of PCBs.

Rapid Electronics Prototyping

Several methods have been proposed to enable rapid electronics prototyping. These methods can be broadly classified into assemblies, additive methods, and subtractive methods. Even though these methods are designed to allow for rapid electronics prototyping, they demonstrate several drawbacks that require improvements in the art to overcome.

Assemblies

One approach to enable rapid electronic prototyping has been to use prefabricated modular electronic components. Aimed at novice users and early learners, products and concepts such as Little Bits describe a collection and the use of electronic modules that snap together using magnetic connectors to form functional circuits.

It has also been proposed that a modular system composed of PCBs that can be arranged in various configurations to produce multiple, different circuits. Some attempts include a method of connecting modular electronic circuits using inkjet-printed conductive traces and conductive tape. Another includes the use of conductive thread and wearable modules for use in e-textiles and interactive clothing. Although these methods are highly configurable, the user is constrained by the limited varieties of pre-existing modules.

Subtractive Methods

Another approach to generate PCBs is to use subtractive methods and techniques. Such methods are similar to carving a sculpture from stone: the process begins with a solid sheet that is whittled away to produce the desired circuit pattern, similar to chemical etching.

Homebrew chemical etching methods utilize home or office printers to create UV masks on cellulose acetate sheets. However, this method is complex to execute, requires considerable expertise, and employs harmful chemicals.

Computer Numeric Control (CNC) machines have been employed to remove the top copper layer from copper-clad boards, forming circuit traces by selectively vaporizing the copper cladding. Although reliable, these techniques require machinery with costs from thousands to tens of thousands of dollars. In contrast, it would be desirable if a PCB film was inexpensive, and required only a standard office printer or similar existing equipment.

Additive Methods

Additive approaches, which deposit electrically conductive traces (including on 3D surfaces), have also been explored. Several commercially available alternatives, such as graphite-based Bare conductive paint and silver-particle-based Circuit Scribe, propose to offer a means to write in conductive ink. While there has been exploration of the use of conductive paint and copper tapes for handcrafting circuits, they may not be quick and easy, and impose limitations due to hand deposition of ink. Such inks are also expensive, such as is the case of Circuit Scribe, or rely on graphite emulsions that do not possess enough conductivity to reliably form connections for small traces. In contrast, in an embodiment, the PCB film may provide traditional copper traces.

Alternative attempts involve the use of inkjet printable silver and copper Nano-particle inks on a paper substrate to create flexible circuits. These methods purport to be fast, easy to use, and employ off the shelf equipment. However, they require the use of specific inkjet cartridges filled with conductive ink and are currently available only for a few selected models of office printers. Commercial systems such as Methode™, AgIC™, Squink™ and ExOne™ use variations of inkjet printing to attempt to rapidly fabricate circuits using such specialized equipment and inks.

It is clear that the ability for end users to quickly, cost-effectively, and easily manufacture high quality PCBs is both elusive and highly desirable. To this end, there is a need for a technology that can be used by anyone, is low-cost, and enables seamless in-office manufacturing of PCBs.

In contrast to the techniques described, the production of a PCB using an embodiment of the PCB film may be easy to use and inexpensive. The PCB films may be created using a printing process to produce a general-purpose PCB. The PCB film may provide instant PCBs in a single printing step. In broad terms, embodiments of the PCB film and the methods for creating a PCB described herein may address one or more of the following needs: rapid production; easy production; low cost of materials; low cost of equipment; no user exposure to toxic chemicals; and high conductivity of resulting circuits.

Described below are examples and embodiments of the layers of the PCB film and its process of manufacturing, along with the considerations in selecting materials, principles of operation, properties of the resulting PCB, the process of attaching components to the resulting PCB, and, finally, any limitations to the resulting circuits, if present.

Composition of PCB Film

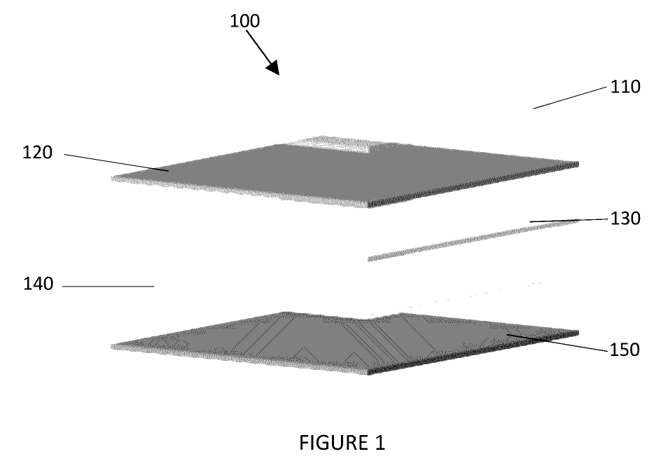

According to an embodiment, a PCB film 100 may comprise the following layers of materials: a layer of radiation-transparent material such as UV-transparent substrate layer 110, a layer of curable adhesive material that may be cured by radiation or other energy, such as UV-curable adhesive layer 120, a layer of electrically conductive or resistive material, such as copper foil layer 130, a layer of adhesive such as holding adhesive layer 140, which may be a pressure-sensitive adhesive according to an embodiment, and a layer of removable material such as peel-off layer 150. These layers are stacked together and bonded to form each sheet of PCB film 100 as shown in FIG. 1. Additional layers of material, such as an adhesive primer layer or adhesive primer layers between each of the five layers described above, may be added according to further embodiments of the invention.

Principle of Operation & Design Implications

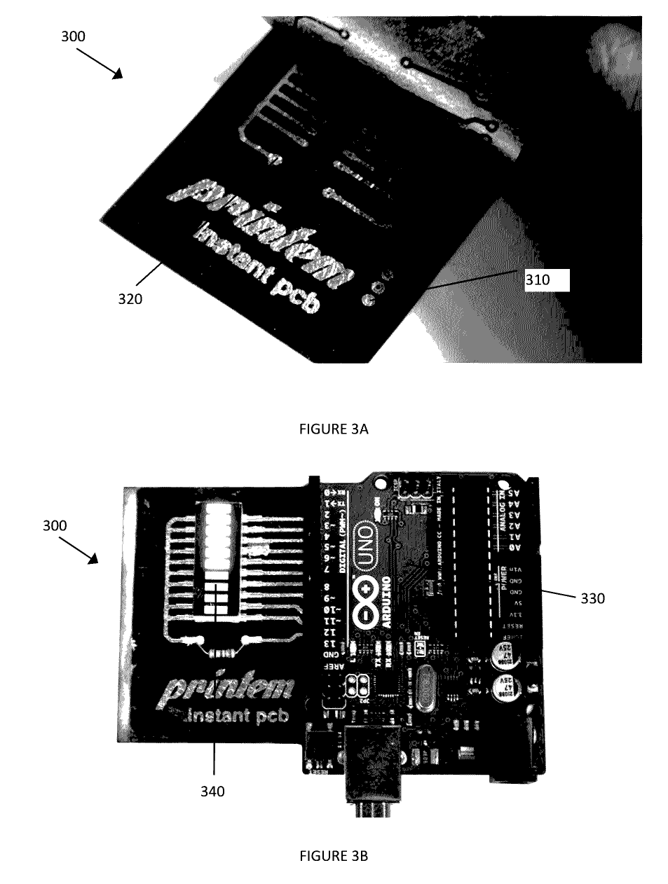

The circuit pattern is printed in negative onto the substrate layer 110 to form an optical mask, which prevents light from passing through the areas where the ink has been deposited. When the film is exposed to light, the areas not covered by the mask allow the light to pass through, thus curing the UV-curable adhesive layer 120 beneath. These selectively cured areas then bond the copper foil layer 130 to the substrate layer 110 more strongly than it is bonded to the holding adhesive layer 140. Thus, when the user removes the peel-off layer 150, the areas of foil that have bonded to it are selectively pulled off, leaving behind the circuit pattern on the substrate layer 110 as shown in FIG. 3.

According to an alternative embodiment, only the substrate layer 110, UV-curable adhesive layer 120 and copper foil layer 130 may be provided. Thus, the excess copper foil layer 130, and, if necessary, UV-curable adhesive layer 120, may be removed by other methods known in the art, such as mechanical of chemical removal.

For the aforementioned process including at least five layers to work best, consideration ought to be given to the strengths of the adhesives that are used between the various layers in the PCB film. According to an embodiment, the adhesives should be of the following relative strengths: bond strength of cured UV adhesive > bond strength of holding adhesive > tear strength of copper foil > bond strength of uncured UV adhesive.

The greater the difference between the strengths, the better the result. To improve results, the materials being bonded to the adhesives may be surface treated with methods such as plasma treatment or abrasion to provide better adhesion. In addition, the composition, construction, and assembly of each layer may be considered.

Substrate Layer

The UV-transparent substrate layer 110 may serve two purposes. Primarily it is the top-most layer, onto which the final copper pattern will be adhered, forming the structural base for the PCB. Additionally, it is the layer onto which the printer will deposit ink or toner to form the optical mask.

According to an alternative embodiment, an end user could print the circuit pattern on the peel off layer 150 and apply the curing step onto the peel off layer 150 and a curable adhesive layer beneath it and between it and the copper foil layer 130. In this embodiment, the peel off layer 150 may be made of a radiation-transparent material, or other material which may allow for the pass through of energy for curing the curable adhesive layer beneath it.

These purposes determine the properties that may be required of this layer. Since this is the substrate for the final PCB, the chosen material for this layer should also be strong enough to resist bending and mechanical stress that it might be subjected to during typical use. This layer should further have an excellent printable surface to allow the formation of a clear, dark, and saturated negative image of the circuit pattern. Additionally, this layer should be able to bond well to the UV-curable adhesive layer 120 below it.

In testing various materials, the chosen material for most of the examples according to embodiments of the invention herein is overhead projector transparencies made of cellulose acetate and possessing an average thickness of 180 microns. These are pre-optimized for printing in both inkjet and laser printers, are inexpensive, and bond well with the UV adhesive. It must be noted that this substrate is not suitable for soldering. In another example, a high-temperature transparent polyimide is substituted for the cellulose acetate, allowing PCBs that are suitable for low-temperature soldering. Similar materials and variants may be known to those skilled in the art, and may depend upon the final application for the PCB. Generally, a chosen material should allow the pass through of the energy for curing the UV-curable adhesive layer 120, which would therefore depend on the material and properties of that layer. Without limitation, other potential substrate materials may include polyimides, polyethlethyl ketones and polytetrafluoroethyelenes.

UV-Curable Adhesive Layer

The UV-curable adhesive layer 120, is made up of an adhesive that cures when exposed to UV light, and is used to coat the copper foil layer 130. The coating should be as uniform as possible, which may be accomplished through application by cylindrical rubber rollers or other means. The UV-curable adhesive layer 120 may provide good bonding properties to both the copper foil layer 130 below it and the substrate layer 110 above it. In its uncured state, it may have sufficient adhesive strength to hold the stack together while being printed on, but it may also have even greater strength in its cured state than that of the holding adhesive layer 140, to enable the copper foil layer 130 to be removed from the substrate layer 110. To reduce production time, the UV-curable adhesive layer 120 may cure quickly when exposed to UV light.

Although general adhesives and custom-engineered adhesives known in the art may be used to ensure performance, in the examples herein the adhesive used is 9001E-V-3.1 from Dymax. 9001E-V-3.1 may leave a residue on the film after it has been peeled off. As an alternative, Tangent Industries makes high-performance adhesives offering a high heat tolerance which may allow one to solder on the substrate without using other component techniques. These may also leave a residue when cured and peeled. As a further alternative, Three Bond is beta testing an adhesive that can be used to form PCB films 100 on any surface, such as walls, tables, floors, etc. It is a UV-reactive pressure sensitive adhesive that becomes tacky when exposed to UV light. As a yet further alternative, Master bond UV15X-6Med-2 is a biocompatible adhesive that may be used to make PCB films 100 that may be stuck to human or animal skin. Several other adhesives are available with similar properties and would also be suitable according to embodiments of the invention; this specific variant was chosen for this embodiment because it meets the above requirements and is safe for handling. As the adhesive coating may be quite thin, even an expensive adhesive may be used according to embodiments of the invention without substantially increasing production cost.

While a UV-curable adhesive layer 120 is described in the embodiments herein, other variants of the adhesive layer 120 and substrate layer 110 are contemplated, as long as the substrate layer 110 can be masked or blocked by the user to create the desired PCB pattern. For example, infrared (IR) or visible light curable adhesive may be used, with corresponding changes to the radiation transparency of the substrate layer 110. Other alternative curing methods, such as thermal curing, chemical curing, and mechanical curing may be used according to further embodiments. Adhesives may also be chosen based on the amount and type of residue that may be left behind after removal. Moreover, various resins may be suitable for use as the adhesive.

According to various embodiments, the adhesive may be very viscous or less viscous such as having a consistency similar to water. The physical properties of the adhesive selected may impact the coating and processing methods used to coat the substrates. These coating methods for depositing UV adhesives, normal adhesives and non-metallic inks and substrates may include spin coating, die coating, knife coating, roller coating, dip coating, curtain coating, spray coating, screen printing and inkjet coating. The methods for depositing metallic substances such as copper foil layer 130 (described more below) may include physical vapor deposition, chemical vapor deposition, electro deposition and electro less deposition.

According to further embodiments, energy curable adhesives may include adhesives that may be cured by visible light, water or heat. According to yet further embodiments, dual curing adhesives may be used which may cure with radiation, such as ultraviolet light, and heat, or radiation, such as ultraviolet light, and moisture, or heat and moisture.

Copper Foil Layer

According to an embodiment, the third layer may be a copper foil layer 130 which may form the electrically conductive portion of the PCB. In the embodiments herein, commonly available copper gilding foil is used. Other metal foils such as silver foils, tin foils, gold foils, aluminum foils, etc. may also be used for this purpose, provided that the material is sufficiently conductive for the purpose of the final PCB and is thin enough that it tears easily when pulled apart. Alternatively, a resistive film may be used so that this layer contains electrically resistive elements.

Copper has one of the highest conductivity-to-price ratios, and is a common choice for traditional PCBs and thus selected for use in the embodiments herein. According to an embodiment, the thickness of this foil may vary between 0.35 microns to 0.55 microns, resulting in a calculated sheet resistance of 0.030 ohm/sq. to 0.056 ohm/sq. Thicker foils may also be used. A consideration when selecting materials is that by using materials used with traditional PCBs, the high conductivity of the chosen foil may allow pre-existing circuit designs to be printed without significant modification.

According to an embodiment, conductivity of the PCBs created using PCB films 100 may be increased by copper or gold plating the traces by depositing enough metal on the traces to bring the thickness of the conductive paths closes to the thickness of the copper foils used in traditional PCBs.

Holding Adhesive Layer

According to an embodiment, underneath the copper foil layer 130 is the holding adhesive layer 140, this adhesive layer 140 binds the copper foil layer 130 to the peel-off layer 150. In an embodiment of the invention, a liquid adhesive by 3M is used because of its availability and adhesion strength. As this adhesive is commonly used to bond layers of paper and cardboard, it may provide a sufficiently strong bond to the peel-off layer 150. According to an embodiment, the adhesive is applied using a spray coating method, whereby the adhesive is deposited with relative uniformity onto the substrate. Other methods of application may be used, such as spin coating, dip coating, screen printing, etc., depending on the adhesive used, the material of the copper foil layer 130 and the material of the peel-off layer 150.

Peel-Off Layer

According to an embodiment, the bottommost layer is the peel-off layer 150, the layer that is peeled away after exposure to light to cure the UV-curable adhesive layer 120. This layer may show adhesion to the holding adhesive layer 140 and be strong enough to not tear when it is being peeled against the forces of the UV-curable adhesive layer 120. According to an embodiment, the peel-off layer 150 may be made from standard 120 GSM card paper, coated with a primer.

PCB Film Assembly

According to an embodiment, after each layer has been stacked, the combined stack may be passed through a pair of rollers to ensure that all five layers are bonded. Any remaining residue from the adhesives may be cleaned off with isopropyl alcohol. The assembly may be carried out in a dimly-lit environment with a light source that does not emit significant UV light to prevent the UV-curable adhesive layer 120 from prematurely curing. The PCB film 100 is then packed into opaque envelopes for storage and later use.

Other methods for coating the substrate layer 110 may be used, including roll-to-roll processing, spin coating, spray coating and chemical vapor deposition. Additional or other restrictions on the manufacturing and storage environment may exist depending on the properties of the curable adhesive layer 120.

PCB Film Properties

The PCBs produced by the PCB film may have several unique properties which may be considered when designing the device they will enable, as well as their circuit layouts.

Trace Widths

Because of its superior conductivity, the PCB film may enable the use of narrower circuit traces than existing ink-based systems. In a traditional PCB, the width of the trace is bounded by the conductivity needs of the circuit and the manufacturing process used. With the materials use in the embodiments described herein, a minimum trace width of 32 mils (˜0.8 mm) was preferred to ensure that sufficient copper foil is left behind when the layers are pulled apart. Further, a minimum spacing between the traces (traditionally equal to one trace width) was also preferred to ensure there are no shorts caused by left behind copper foil. However, these widths are dependent on numerous factors, and each should be considered for determining minimum requirements. For example, the uniformity of adhesive distribution, ranging from hand application, to the roller process described in the embodiments herein, to computer-controlled spray depositing, may affect the minimums based on the degree and quality of adherence. Similarly, the uniformity and quality of the copper foil layer 130 may affect the minimums, as more uniform and finished materials may decrease the minimum requirements.

Flexibility

According to an embodiment, the PCB film 100 may be generally sufficiently flexible in order for it to pass through the paper path of a common printer. Naturally, the resulting PCBs are also flexible, enabling them to be mounted onto non-planar surfaces, or even in uses where they will be continually flexed. If the particular application of the PCB being produced requires rigidity, such as in the common situation in which assemblies commonly rely on the PCB to provide structure and form, the PCB film may be attached to a rigid substrate to provide such a structure.

Size & Scale

The size of the PCB films 100 may be practically limited by the scale at which the adhesive layers may be uniformly applied although in industrial production (as opposed to end user production) this will be very large. Beyond this, another size limitation factor may be an end user requirement, that is, the sheet feed size of the target printer, which may print on various preset sizes, such as 8.5 by 11 inches, 8.5 by 14 inches or 8.5 by 17 inches. To assist, a software tool may be used to implement the tiling of a PCB across multiple sheets of PCB film 100 if a larger PCB is desired to be created with such a printer. These sheets could then be connected via traditional methods, such as those used to attach components.

Achieving Multi-Circuits

Multi-layer circuits may also be created according to certain embodiments of the invention. The first approach is to create single layer circuit panels as described herein and put them through the traditional manufacturing process as traditional rigid and flexible PCBs to create the multilayer circuits.

The second approach is to combine the single layer PCB films by laser cutting and drilling interconnects and then bonding and plating the interconnects, and repeating for each additional single layer PCB film that was to be added. According to an embodiment, this approach may use existing conductive inks, electro plating, or conductive epoxies to form the interconnects after the appropriate holes have been drilled using the laser. This way we may create a stack of as many PCBs as needed. The substrates may be configured or modified to suit such a stacking approach, for example, the substrates may be made heat bondable. According to an embodiment, the laser may be substituted with a depth controlled drill.

According to further embodiments, riveting and spot welding may be used to create 2-layer PCB boards. After forming the patterns on both sides of a double-sided PCB film, then the user or an automated process may manually punch micro rivets through the layers to form the interconnects. Such micro rivets are already available in the market for use in miniature sheet metal assembly.

With spot welding, after forming a two-layer PCB sheet with copper patterns on either side of the substrate, heat and pressure may be used to spot weld the foils of copper through the substrate thus forming the necessary interconnections. Spot welding may, however, be challenging when using conductive foils that are very thin.

As a further alternative embodiment, a small flap of conductive material may be cut using a laser and then folded to the other side and then soldered to form an interconnection.

### EXAMPLES

The PCB film 100 may enable rapid, easy, and safe production of PCBs. In order to produce a working device from a PCB film, the end user may complete this by designing, printing, and peeling their PCB from the PCB film, as described herein, and then attaching their various device components, of which several examples are described further below.

Creating the PCB

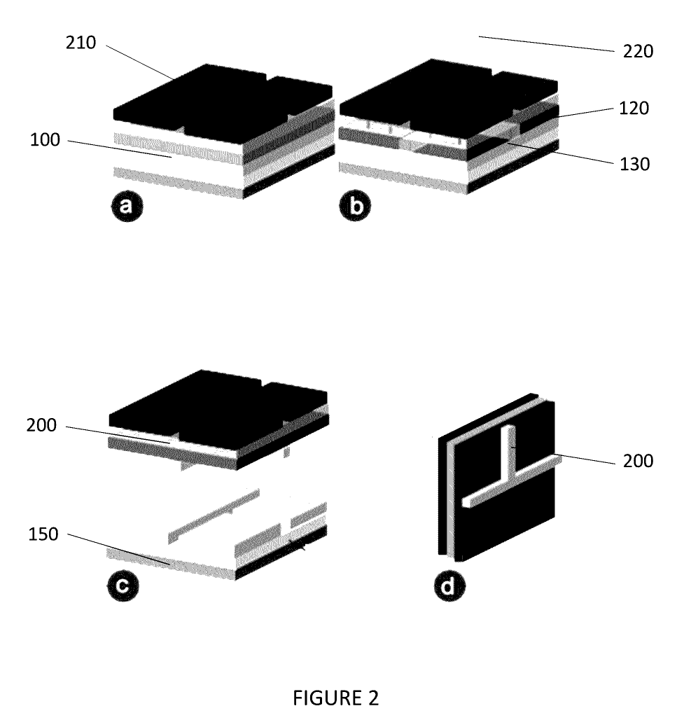

According to an embodiment as shown in FIG. 2, to create a PCB, the PCB film 100 is covered (step a) with a layer of ink 210, typically by passing through an inkjet or laser printer. The layer of ink 210 defines the circuitry of the desired PCB. Next, the ink-covered PCB film is exposed to UV radiation 220 (step b), curing the UV-curable adhesive layer 120 in the exposed areas. Once fully cured, the peel-off layer 150 is removed (step c), along with the adhesive layer 140 and the non-bonded parts of copper foil layer 130, leaving the PCB 200 ready for use (step d).

According to an embodiment, the light from a light-emitting display on a phone, a laptop, a tablet, or a projector may be used to cure the adhesive layer 120. In this embodiment, a circuit pattern may be displayed in black and white at a high brightness on the light-emitting display of the device. The printable film may then be placed adjacent to the display and the areas of the film next to white light may cure, without curing the areas next to the black pixels on the display. According to this embodiment, the curable adhesive layer 120 is curable by visible light, and, for example, a visible light curing resin may be used.

Component Assembly

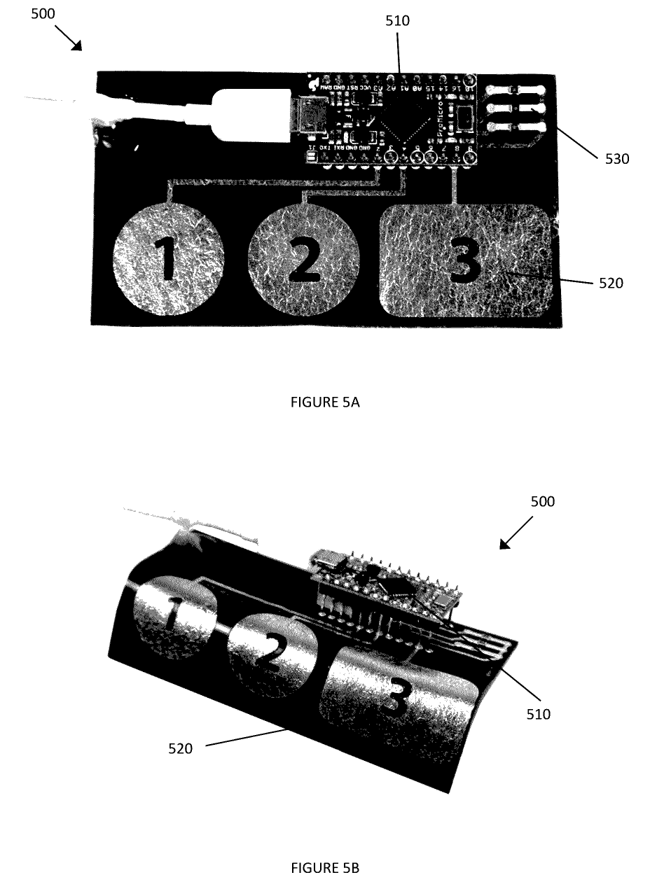

After a PCB has been created from the PCB film, the various ICs and components are affixed. The PCB may be compatible with a wide variety of component assembly techniques. A common procedure in electronics fabrication is to solder the contacts on each component to the corresponding copper traces on the PCB. By using a heat-resistant polyimide film as the substrate 110, the PCB film 100 may allow for low-temperature soldering using a Tin-Bismuth solder with a nominal working temperature of 145° C. (see FIG. 5), a significant advantage over PCBs produced on paper with conductive inks, which cannot resist high temperatures.

The PCB film 100 may also be compatible with Z-Tape, a special material that can conduct electricity perpendicular to its surface but not transverse to it. This tape may be used to quickly “stick” component modules in place to assemble circuits. The use of the tape offers an additional advantage over soldering in that components connected to the PCB can be quickly and easily removed, allowing for reuse.

Another method for the assembly of many components is to use laser- or paper-cut stencils to apply conductive adhesive over the PCB. In testing, the components only have to be placed on top of the conductive adhesive in order to strongly bond to the PCB film after curation. The stencil method may also be used to apply solder paste and the reflow-soldering technique may affix components; this is a common way of assembling surface mount components in the industry.

Example Applications

To demonstrate the various uses of PCB film 100 according to embodiments of the invention, four examples are described herein: a simple Arduino™ Shield, a plant soil moisture sensor, a Physical Shortcut Pad, and a Paper Speaker. Each of these exhibits one or more attributes of PCB film 100.

### Example 1: Arduino™ Shield

To demonstrate the quick prototyping use of PCB film, a simple LED bar graph shield for the Arduino Uno™ may be built. Due to the simplicity and rapidity of using PCB film 100, such ad hoc circuits may be tested quickly and then cut into a variety of shapes for later use.

FIGS. 3A and 3B show the Arduino™ shield 300. As shown in FIG. 3A, the attachment points 310 for the Arduino™ pin-outs are on the right side of the PCB, and the leads and mount points 320 for each LED in the array are in the center, along with the leads and mount points for a single resistor beneath the array. FIG. 3B shows the working PCB 300, where the Arduino Uno 330™ is controlling the LED array 340. In this example, the PCB was printed in several seconds, plus an additional two minutes to cure. Components were then attached using a stencil, as described above. Also, while the PCB is generally flexible, this device is better provided with rigidity. To this end, the PCB was affixed to a rigid substrate.

### Example 2: Green Thumb

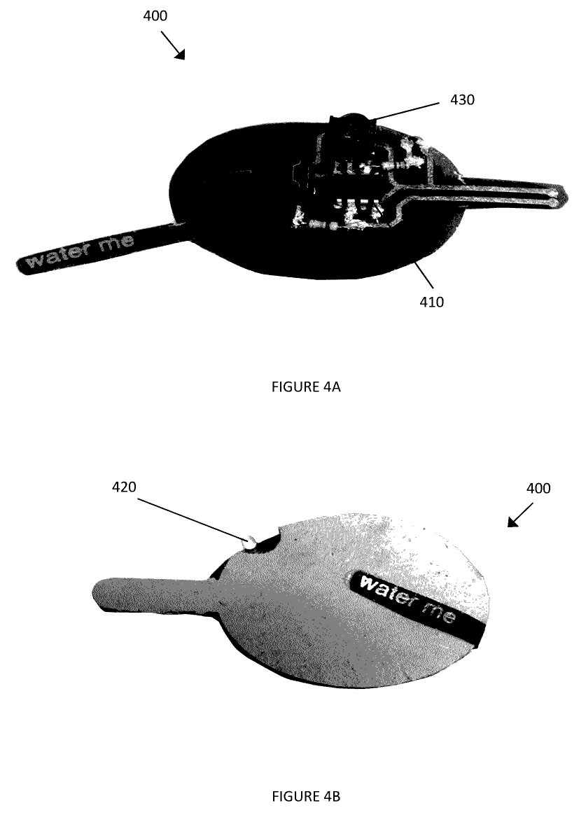

As shown in FIGS. 4A and 4B, this device 400 indicates when a plant needs to be watered. The circuit consists of an Attiny85™ microcontroller 410 that repeatedly measures the resistance of the soil, triggering a red LED 420 whenever the moisture falls below a certain threshold set using the onboard potentiometer 430. For assembly, the components have been affixed to the PCB using conductive epoxy as shown in FIG. 4A, but without the use of a mask, after making holes in the PCB at the right places, the components are inserted through and the conductive epoxy is applied. Finally, scissors are used to cut the PCB to the desired shape.

### Example 3: Physical Shortcut Pad

As shown in FIGS. 5A and 5B, the flexibility of PCB film 100 may be leveraged to create objects with interesting shapes, using the PCB film 100 to create componentry, rather than simply the traditional elements of a PCB. In this case, a simple user interface device: a shortcut pad 500 that triggers various shortcuts in OSX. An Arduino Pro Micro™ 510 has been combined with a simple capacitive sensing technique to create a touchpad 520. The circuit triggers a keyboard command through the USB whenever the touchpad 520 on the PCB is touched. The physical substrate was created using a laser-cut acrylic that was reshaped with a heat-gun, onto which the PCB was mounted. As shown in FIG. 5B, the PCB is then adhered to a bent acrylic mounting.

Naturally, traditional buttons could have been mounted onto the PCB if desired. However, the use of the PCB film 100 to create the input pad itself demonstrates the sort of flexible prototyping that the PCB film 100 affords. Also, the PCB film 100 used is suitable for use with surface-mount components, such as the resistors 530 mounted to the right of the Arduino™ board 510.

### Example 4: Paper Speaker

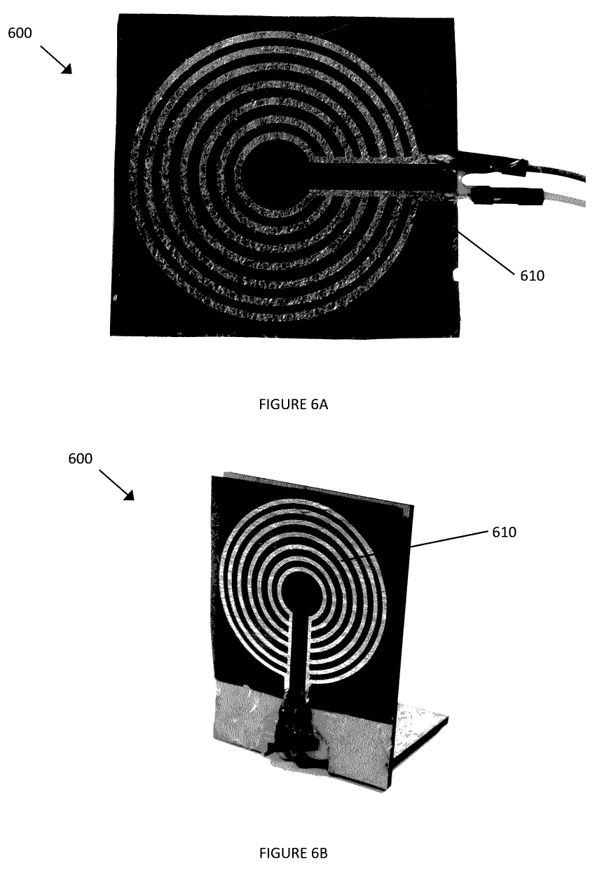

As shown in FIGS. 6A and 6B, the flexibility of PCB film 100 is used to create a paper speaker 600. The PCB film is used to produce the voice coil 610 (the copper rings as shown in FIG. 6A). The speaker 600 produces sound by applying a variable current to the voice coil 610, which causes it to act as an electromagnet, alternately attracting and repelling the magnet 620 mounted behind it, visible in FIG. 6B. This produces a mechanical movement of the entire PCB, which in turn produces the sound. The assembly is driven using an Arduino™ amplifier, not shown.

Throughout this disclosure, the term “film” is used. This is intended to describe the arrangement of layers rather than to limit physical characteristics or other aspects of the material and resulting product.

Throughout this disclosure, the term “transparent” is used. The reader will understand that “transparent”, as used in the context of this patent, does not imply 100% transmission of a given radiation. The techniques disclosed herein are effective with far lower rates of transmission.

The present invention may be embodied in other specific forms without departing from the spirit or essential characteristics thereof. Certain adaptations and modifications of the invention will be obvious to those skilled in the art. Therefore, the presently discussed embodiments are considered to be illustrative and not restrictive, the scope of the invention being indicated by the appended claims rather than the foregoing description and all changes which come within the meaning and range of equivalency of the claims are therefore intended to be embraced therein.

What is claimed is:

1. A film for use in the preparation of a printed circuit board (PCB), comprising:
a first layer formed of a radiation-transparent material;
a second layer formed of a curable adhesive material, the second layer adjacent to and adhered to the first layer, the adhesive material being curable via exposure to radiation; and
a third layer formed of an electrically conductive material, the third layer adjacent to and adhered to the second layer.

2. The film of claim 1, further comprising:
a fourth layer formed of an adhesive, the fourth layer adjacent to and adhered to the third layer; and
a fifth layer formed of a removable material, the fifth layer adjacent to and adhered to the fourth layer such that, when the fifth layer is removed, at least part of the fourth layer and at least part of the third layer are additionally removed.

3. The film of claim 1, wherein the electrically conductive material of the third layer includes one of: copper, tin, aluminum, gallium, iridium, gold, silver, and indium tin oxide.

4. The film of claim 3, wherein the electrically conductive material of the third layer includes copper.

5. The film of claim 1, wherein the radiation-transparent material is transparent to one of: infrared (IR) radiation, ultraviolet (UV) radiation, and visible light radiation.

6. The film of claim 1, wherein the radiation-transparent material allows transmission of at least 50 percent of the radiation to which it is exposed.

7. The film of claim 1, wherein the radiation-transparent material allows transmission of 50 percent or less of the radiation to which it is exposed.

8. The film of claim 2, wherein the removable material is one of: paper, cardboard, and plastic.

9. The film of claim 1, wherein the adhesive material is curable by exposure to one of: infrared (IR) radiation, ultraviolet (UV) radiation, and visible light radiation.

10. The film of claim 1, wherein the radiation-transparent material is transparent to radiation which is the same as the radiation for curing the curable adhesive.

11. The film of claim 2, wherein the bond strength of the second layer formed of the curable adhesive material once cured is greater than the bond strength of the fourth layer formed of the adhesive.

12. The film of claim 2, wherein the bond strength of the fourth layer formed of the adhesive is greater than the tear strength of the third layer formed of the electrically conductive material.

13. The film of claim 1, wherein the tear strength of the third layer formed of the electrically conductive material is greater than the bond strength of the curable adhesive material before it is cured.

14. A method of creating a printed circuit board (PCB), comprising:
taking a printable film, the printable film comprising:
a first layer formed of a radiation-transparent material;
a second layer formed of a curable adhesive material, the adhesive material being curable via exposure to radiation;
a third layer formed of an electrically conductive material;
depositing ink on to the radiation-transparent layer of the film, the ink distributed in a pattern representing the PCB;
exposing the ink-covered film to radiation, the radiation curing the curable adhesive material; and
removing part of the third layer of electrically conductive material such that portions of the electrically conductive material remain in the pattern to form the PCB.

15. The method of claim 14, wherein:
the printable film additionally comprises a fourth layer formed of an adhesive; and
a fifth layer formed of a removable material;
and the removing step includes removing the fifth layer of removable material from the film, thereby removing the parts of the third layer of electrically conductive material with the fifth layer of removable material.

16. The method of claim 15, wherein the removing step removes parts of the fourth layer when the fifth layer is removed.

17. The method of claim 14, wherein the ink is distributed on the film by a printer.

18. The method of claim 14, wherein the radiation curing the curable adhesive material is from a light-emitting device displaying a circuit pattern.

19. A method of producing a printable film for use in the preparation of a printed circuit board, comprising:
bonding a plurality of layers into the printable film, the layers including:
a first layer formed of a radiation-transparent material;
a second layer formed of a curable adhesive material, the adhesive material being curable via exposure to radiation, bonded to the first layer; and
a third layer formed of an electrically conductive material, bonded to the second layer.

20. The method of claim 19, further comprising bonding a fourth layer formed of an adhesive to the third layer and bonding a fifth layer formed of a removable material to the fourth layer.

21. The method of claim 19, further comprising a step of pressing the layers together to enhance bonding.

22. The method of claim 19, wherein the steps of the method are carried out in an environment without enough radiation to cure the curable adhesive material.
